(19) United States
(12) Patent Application Publication
(10) Pub. No.: US 2011/0155568 A1
(43) Pub. Date: Jun. 30, 2011

(54) INDEXING MAGNET ASSEMBLY FOR ROTARY SPUTTERING CATHODE

(75) Inventors: Daniel Theodore Crowley, Owatonna, MN (US); Jerome Kevin Kelly, Faribault, MN (US)

(73) Assignee: SPUTTERING COMPONENTS, INC., Owatonna, MN (US)

(21) Appl. No.: 12/648,555

(22) Filed: Dec. 29, 2009

(51) Int. Cl. C23C 14/54; C23C 14/35

(52) U.S. Cl. 204/298.09; 204/298.16

(57) ABSTRACT

A magnet assembly for a rotary cathode having a rotatable target cylinder is provided. The magnet assembly comprises a coolant tube configured to be positioned within the target cylinder, and a magnet bar configured to be positioned within the target cylinder and extending substantially parallel to the coolant tube. The magnet bar moves laterally with respect to the target cylinder in a synchronous manner with rotation of the target cylinder.

### BACKGROUND

A magnetron sputtering device is used to deposit thin film layers on a substrate. The magnetron sputtering device utilizes a rotary cathode having a hollow target cylinder that carries a target material for sputtering. The target cylinder is rotated around a stationary magnet suspended inside of the cylinder. The magnet is directed at a substrate in a vacuum chamber and holds processing plasma in a desired location for coating the target material on the substrate. A coolant such as water typically flows inside the target cylinder for cooling during the sputtering process.

During operation of the magnetron sputtering device, erosion of the target material on the target cylinder typically occurs in a non-uniform manner such that radial grooves are formed at the ends of the target material. This leaves a substantial amount of target material unused when the target cylinder needs to be replaced.

As target materials for rotary cathodes are highly expensive, it is desirable to find ways to prolong the useful life of such materials before replacement of the target cylinder is required.

### SUMMARY

The present invention relates to a magnet assembly for a rotary cathode having a rotatable target cylinder. The magnet assembly comprises a coolant tube configured to be positioned within the target cylinder, and a magnet bar configured to be positioned within the target cylinder and extending substantially parallel to the coolant tube. The magnet bar moves laterally with respect to the target cylinder in a synchronous manner with rotation of the target cylinder.

### BRIEF DESCRIPTION OF THE DRAWINGS

Features of the present invention will become apparent to those skilled in the art from the following description with reference to the drawings. Understanding that the drawings depict only typical embodiments of the invention and are not therefore to be considered limiting in scope, the invention will be described with additional specificity and detail through the use of the accompanying drawings, in which:

FIG. 1 is a partial cross-sectional side view of a rotary cathode that includes a magnet assembly according to one embodiment;

FIG. 2 is a perspective view of an indexing magnet assembly for a rotary cathode according to another embodiment;

FIG. 3 is a partial cross-sectional side view of the indexing magnet assembly of FIG. 2;

FIG. 4 is an end view of the indexing magnet assembly of FIG. 2;

FIG. 5A is a cut away side view of a rotary cathode that includes the indexing magnet assembly of FIG. 2;

FIG. 5B is a partial perspective view of the rotary cathode shown in FIG. 5A;

FIGS. 6A-6F illustrate a pattern of incremental movements of a magnet bar in the rotary cathode of FIG. 5A;

FIG. 7 illustrates a cross-sectional side view of a magnetron sputtering apparatus that includes a rotary cathode without an indexing magnet assembly;

FIG. 8 illustrates a cross-sectional side view of a magnetron sputtering apparatus that includes a rotary cathode having the indexing magnet assembly of FIG. 2; and

FIG. 9 is a partial cross-sectional side view of a rotary cathode that includes an indexing magnet assembly according to a further embodiment;

### DETAILED DESCRIPTION

In the following detailed description, embodiments are described in sufficient detail to enable those skilled in the art to practice the invention. It is to be understood that other embodiments may be utilized without departing from the scope of the present invention. The following description is, therefore, not to be taken in a limiting sense.

The present invention relates to an indexing magnet assembly for a rotary sputtering cathode, which provides for increased utilization of a target material on a target cylinder of the cathode during a sputtering operation. The indexing magnet assembly provides for incremental movement of the sputter region on a rotating cathode in a back-and-forth pattern to prevent deep erosion of the target material in one place.

In one embodiment, a magnet bar is attached to a coolant tube such that the magnet bar can move freely in a lateral direction. The target cylinder is rigidly attached to structures that effectively cap the end of the cylinder. As the cylinder rotates on its axis, there is a mechanical interaction between one of the capping structures, rotating with the target, and the magnet assembly that does not rotate with the target. This interaction causes the magnet bar to move laterally in a synchronous fashion with the cylinder rotation. In another embodiment, the coolant tube and magnet bar are combined and move together to create lateral motion of the entire magnet bar assembly.

As used herein, “synchronous lateral motion” refers to the motion of the magnet bar in conjunction with target cylinder rotation such that the specific lateral position of the magnet bar will repeat in a relatively small number of rotational cycles. The lateral motion of the magnet bar moves the erosion groove of the target material so that it is not always in the same place, which increases the useful life of the target material, thereby avoiding early replacement costs. In addition, the frequency of target cylinder changes is reduced, saving down time and maintenance costs.

Various aspects of the present invention are discussed in further detail hereafter with reference to the drawings.

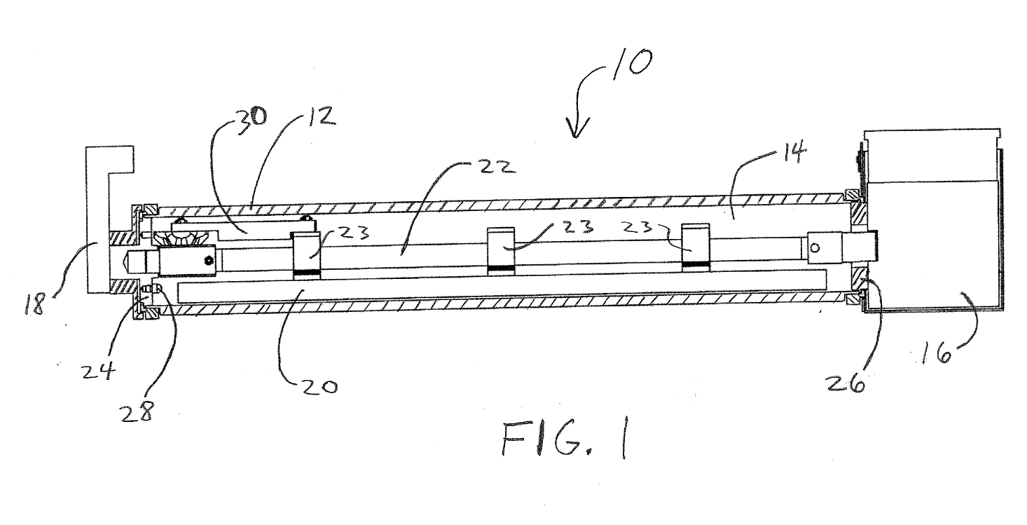

FIG. 1 illustrates a rotary cathode 10, which includes an indexing magnet assembly according to one embodiment. The rotary cathode 10 has a rotatable target cylinder 12 with an interior passageway 14. The rotary cathode 10 is removably coupled to a cathode end block 16, which contains a rotary drive mechanism for providing rotational motion to target cylinder 12. An outboard support structure 18 is coupled to an opposite end of rotary cathode 10 to provide horizontal support.

A magnet bar 20 is slidably attached to a coolant tube 22, such as with one or more tube clamps 23, within interior passageway 14 of target cylinder 12. The magnet bar 20 and tube clamps 23 can move freely in a lateral direction with respect to coolant tube 22. The target cylinder 12 is rigidly attached to capping structures that effectively cap the ends of target cylinder 12, such as a target end cap 24 and a target mounting flange 26. As target cylinder 12 rotates on its axis, there is mechanical interaction between at least one of the capping structures, rotating with target cylinder 12, and the magnet assembly that does not rotate with target cylinder 12. In one embodiment, this interaction is caused by a drive pin 28 that engages with an indexing wheel and connecting arm assembly 30. One or more drive pins may be used, and these drive pins may be mounted on either or both capping structures. The indexing wheel is partially turned when engaged by the pin, causing the indexing wheel to pull or push on the connecting arm, which moves magnet bar 20 in a lateral direction. This type of mechanical engagement causes magnet bar 20 to have a synchronous lateral motion such that the specific lateral position of magnet bar 20 is repeated in a predetermined number of rotational cycles, usually less than 17. In the embodiment shown in FIG. 1, the number of target rotations required to make a full cycle of lateral movement is an integer number, equal to the number of teeth on the indexing wheel.

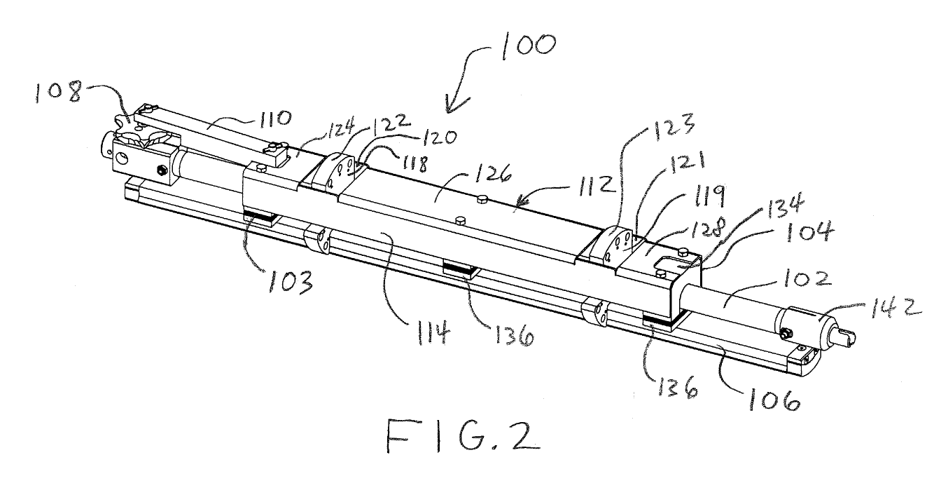

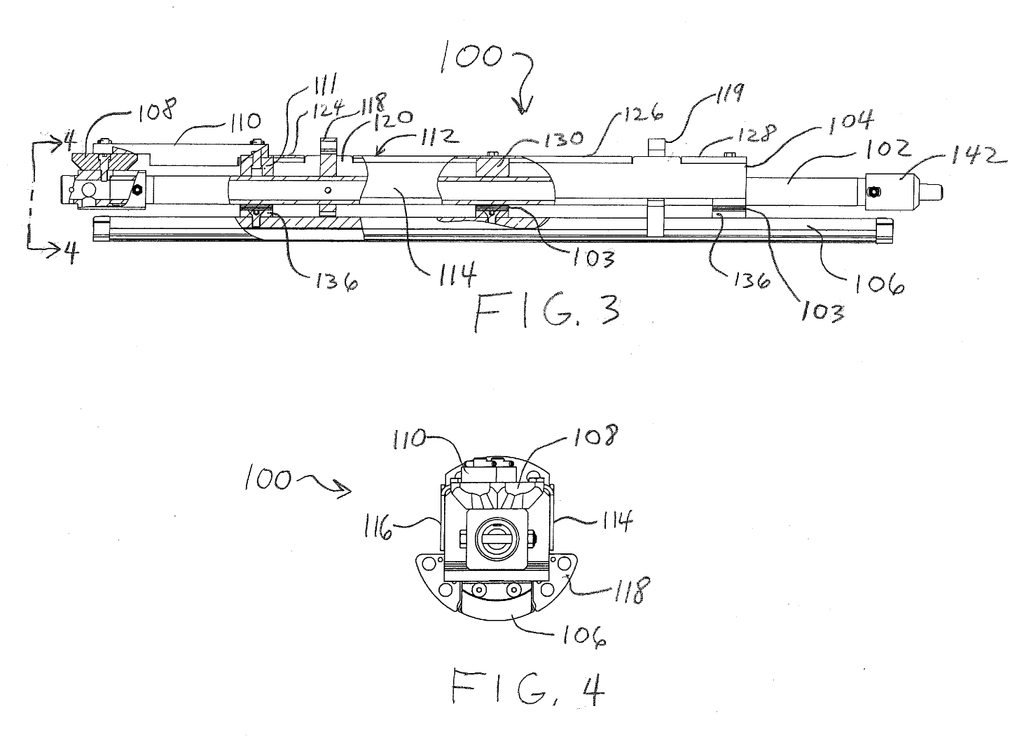

FIGS. 2-4 illustrate an indexing magnet assembly 100 for a rotary sputtering cathode according to another embodiment. The indexing magnet assembly 100 generally includes a tube 102 such as a coolant tube having a proximal end and a distal end. A stiffening structure 104 at least partially surrounds tube 102 and is laterally movable with respect to tube 102. A magnet bar 106 extends substantially parallel to tube 102 and is spaced apart from tube 102 with one or more uniformity adjustment spacers 103. The magnet bar 106 is connected to stiffening structure 104 and is laterally movable with stiffening structure 104. An indexing wheel 108 is rotatably attached to the distal end of tube 102 separate from stiffening structure 104. A connecting arm 110 has one end attached to indexing wheel 108 and the other end attached to a tube clamp 111, as shown most clearly in FIG. 2. The tube clamp 111 is connected to stiffening structure 104. When indexing wheel 108 rotates, connecting arm 110 synchronously moves tube clamp 111, stiffening structure 104, and magnet bar 106 in a lateral direction with respect to tube 102.

The stiffening structure 104 has three sides, including an upper side 112 extending substantially parallel to tube 102, and a pair of opposing sides 114, 116. The upper side 112 has at least one aperture 120 that permits an upper surface 122 of a support disc 118 to protrude outside of stiffening structure 104. As depicted in the embodiment of FIGS. 1 and 2, upper side 112 also has a second aperture 121 that permits an upper surface 123 of a support disc 119 to protrude outside of stiffening structure 104. The support discs 118, 119 are fixed to tube 102 to center the entire assembly inside a target cylinder for aiding in the installation of the entire assembly into the end fixtures of the cathode, no matter what the orientation of the magnet bar is inside the target cylinder. These support discs may also be used to mount support rollers for long magnet assemblies. Support rollers can be mounted in many orientations to allow for sputtering in any direction. The apertures 120 and 121 divide upper side 112 into a distal section 124, a central section 126, and a proximal section 128. The connecting arm 110 has one end attached off center to indexing wheel 108 and the other end attached tube clamp 111, which is attached to distal section 124 of upper side 112.

At least one tube clamp 130 is attached to central section 126 of upper side 112 within stiffening structure 104 and holds tube 102 in a fixed position while being slidable along tube 102. Additional tube clamps can be utilized as needed, such as tube clamp 134 attached to proximal section 128 of upper side 112. Each of the tube clamps include a support plate 136 attached to magnet bar 106, and sandwiching uniformity adjustment spacers 103 interposed between support plate 136 and tube 102. A bushing 142 located at the proximal end of tube 102 allows tube 102 to be sealingly coupled to a hollow water tube of a rotary cathode.

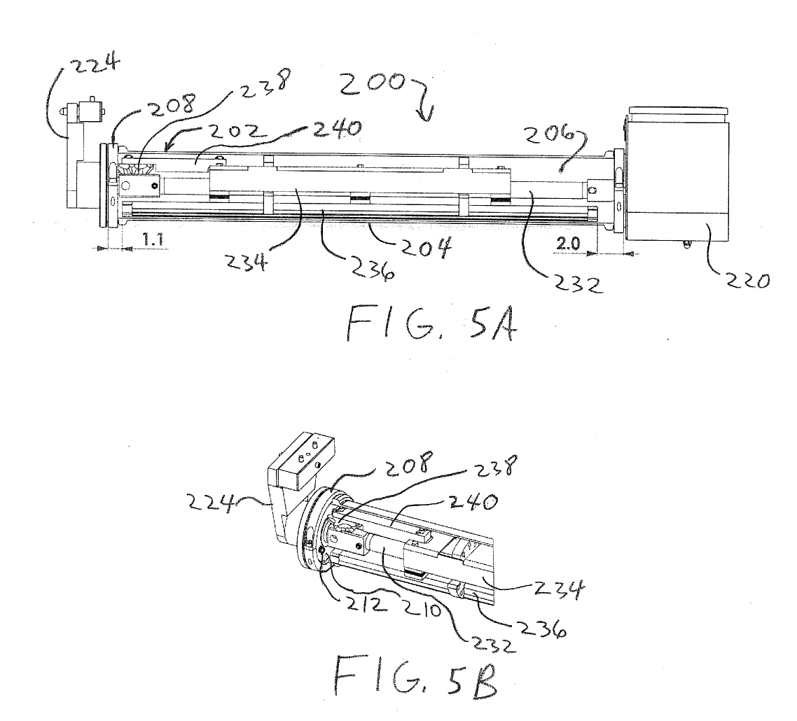

FIGS. 5A and 5B depict a rotary cathode 200, which includes an indexing magnet assembly as discussed previously. The rotary cathode 200 includes a rotatable target cylinder 202 having an outer surface 204 and an interior passageway 206. In one embodiment, target cylinder 202 has a target material on outer surface 204. In another embodiment, target cylinder 202 is composed of the target material.

An end cap 208 is affixed at a distal end of target cylinder 202 and has an inner surface 210 facing interior passageway 206. As shown in FIG. 5B, end cap 208 also has an indexing pin 212 that protrudes from inner surface 210. The rotary cathode 200 is removably coupled to a cathode end block 220 at a proximal end of rotary cathode 200. The end block 220 contains a rotary drive mechanism for providing rotational motion to rotary cathode 200. In addition, an outboard support structure 224 is coupled to end cap 208 to support rotary cathode 200 in a horizontal position within a vacuum chamber.

The indexing magnet assembly in target cylinder 202 includes the same components as discussed above for indexing magnet assembly 100. As such, a coolant tube 232 is positioned within interior passageway 206 of target cylinder 202. A stiffening structure 234 is located in interior passageway 206, with stiffening structure 234 being laterally movable with respect to coolant tube 232. A magnet bar 236 extends substantially parallel to coolant tube 232 and is spaced apart from coolant tube 232 with uniformity spacers. The magnet bar 236 is connected to stiffening structure 234 and is laterally movable with stiffening structure 234. An indexing wheel 238 is rotatably attached to a distal end of coolant tube 232. A connecting arm 240 is attached to indexing wheel 238 and a tube clamp.

When rotary cathode 200 rotates, indexing pin 212 periodically engages with indexing wheel 238. This causes incremental movement of indexing wheel 238 such that connecting arm 240 pushes or pulls stiffening structure 234 and connected magnet bar 236 in a lateral direction with respect outer surface 204 of target cylinder 202. As discussed hereafter, this incremental movement occurs in several stages such that for every rotation of target cylinder 202, magnet bar 236 incrementally moves away from end cap 208 for a few rotations, and then incrementally moves toward end cap 208 for a few rotations. This pattern of back and forth incremental movements of magnet bar 236 continually repeats itself during rotation of rotary cathode 200.

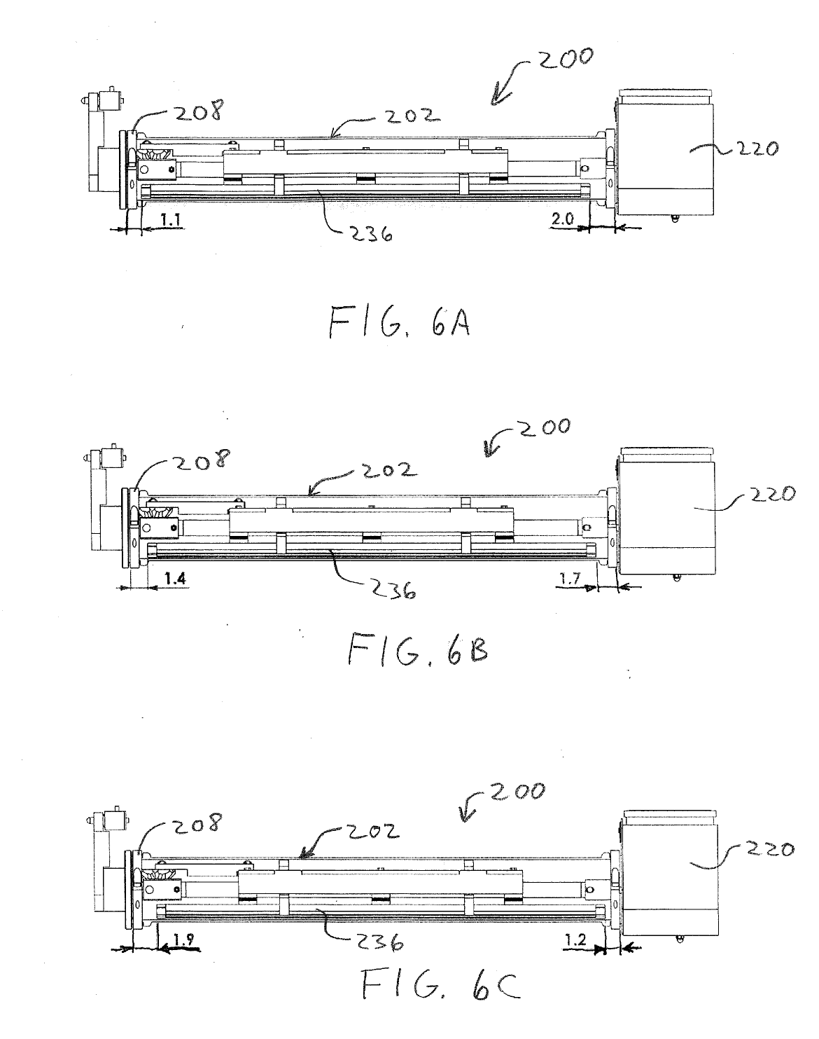

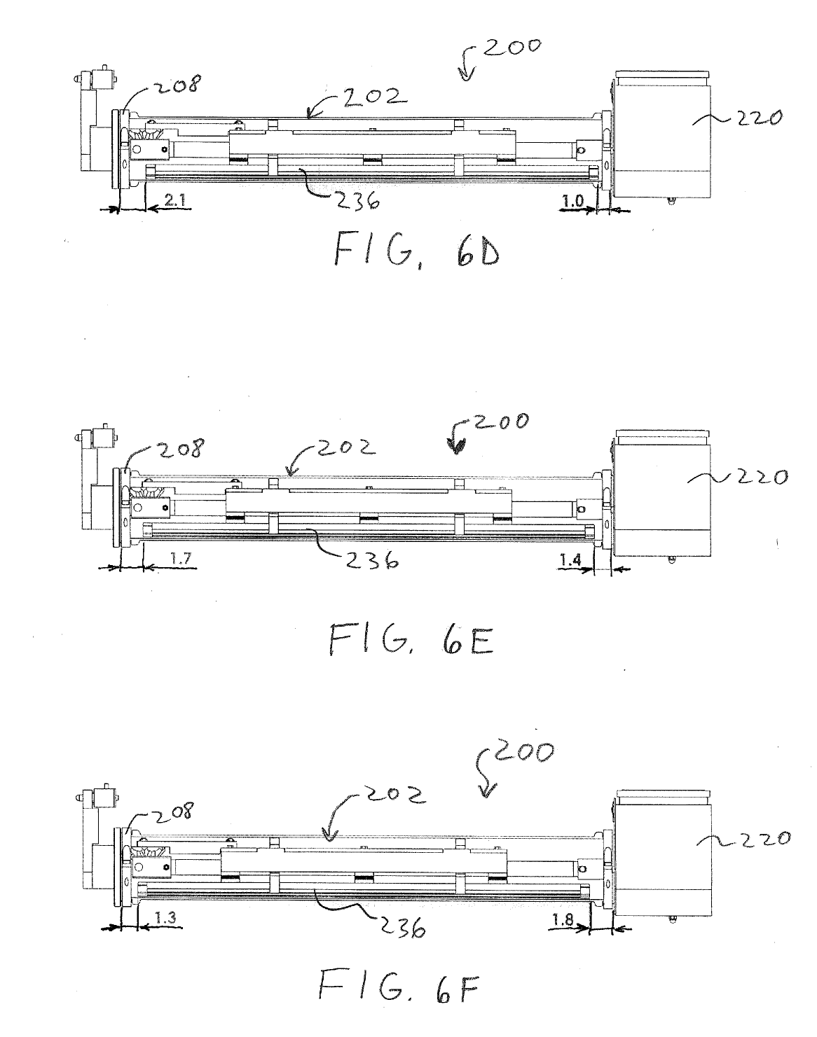

FIGS. 6A-6F illustrate a six-position pattern of incremental movements of the indexing magnet assembly in rotary cathode 200 according to one embodiment. It should be understood that fewer or greater than six positions can be implemented as needed for a particular rotary cathode. The distance numbers discussed with respect to FIGS. 5A-5F are only exemplary and can be varied depending on the size of the rotary cathode and magnet bar. In addition, the distance numbers can be for various units of measurement such as centimeters, inches, or the like.

At a first position shown in FIG. 6A, a distal end of magnet bar 236 is at a first distance (1.1) from end cap 208, and a proximal end of magnet bar 236 is at a second distance (2.0) from end block 220. During one rotation of target cylinder 202 of rotary cathode 200, magnet bar 236 is incrementally moved to a second position as shown in FIG. 6B. At the second position, the distal end of magnet bar 236 is at an increased distance (1.4) from end cap 208, and the proximal end of magnet bar 236 is at a reduced distance (1.7) from end block 220. During the next rotation, magnet bar 236 is incrementally moved to a third position as shown in FIG. 6C. At the third position, the distal end of magnet bar 236 is at a further increased distance (1.9) from end cap 208, and the proximal end of magnet bar 236 is at a further reduced distance (1.2) from end block 220. In the following rotation of target cylinder 202, magnet bar 236 is incrementally moved to a fourth position as shown in FIG. 6D. At the fourth position, the distal end of magnet bar 236 is at an additional increased distance (2.1) from end cap 208, and the proximal end of magnet bar 236 is at a further reduced distance (1.0) from end block 220.

During the next rotation of target cylinder 202, magnet bar 236 is incrementally moved to a fifth position as shown in FIG. 6E. At the fifth position, the distal end of magnet bar 236 is at a decreased distance (1.7) from end cap 208, and the proximal end of magnet bar 236 is at an increased distance (1.4) from end block 220. During the following rotation, magnet bar 236 is incrementally moved to a sixth position as shown in FIG. 6F. At the sixth position, the distal end of magnet bar 236 is at a further decreased distance (1.3) from end cap 208, and the proximal end of magnet bar 236 is at an additional increased distance (1.8) from end block 220. As the target cylinder 202 continues to rotate during operation of rotary cathode 200, the foregoing pattern of incremental movements for magnet bar 236 in FIGS. 6A-6F is repeated.

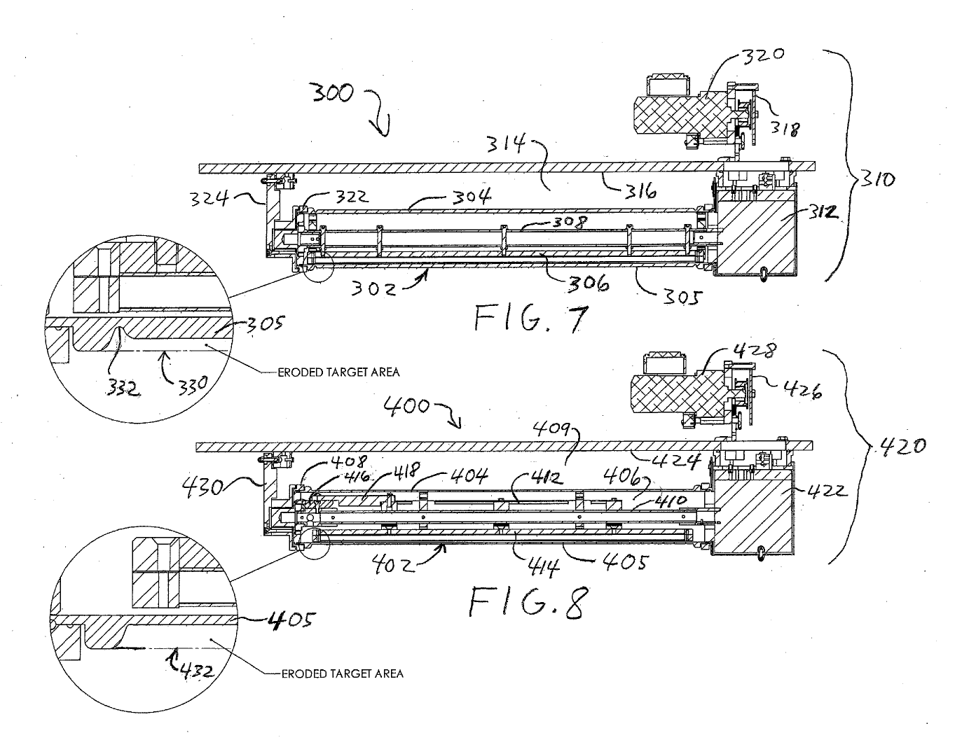

FIG. 7 illustrates a magnetron sputtering apparatus 300 that includes a rotary cathode 302 without the indexing magnet assembly described previously. The rotary cathode 302 includes a target cylinder 304 with a target material layer 305 on an outer surface thereof. The target cylinder 304 is rotatable around a stationary magnet bar 306 that is suspended inside of target cylinder 304 from a coolant tube 308. A cathode source assembly 310 includes a cathode end block 312 that surrounds a hollow drive shaft (not shown). The end block 312 is coupled to a proximal end of target cylinder 304 in a vacuum chamber 314. The end block 312 is also attached to a vacuum chamber wall 316. A drive housing 318 is located outside of vacuum chamber 314 and is operatively coupled to end block 312 through vacuum chamber wall 316. A motor 320 is mounted on drive housing 318. An end cap 322 is secured at a distal end of target cylinder 304. An attachment mechanism 324 rotatably couples end cap 322 to an interior surface of vacuum chamber wall 316 to support rotary cathode 302 in a horizontal position.

The enlarged sectional view of rotary cathode 302 in FIG. 6 shows an eroded target area profile 330 for target material layer 305 on the outer surface of target cylinder 304. The eroded target area has an erosion groove 332 formed between each end of target cylinder 304 that is deeper than the remaining target material between the ends of the target cylinder. This remaining target material goes unused as the target cylinder needs to be replaced because of the erosion groove.

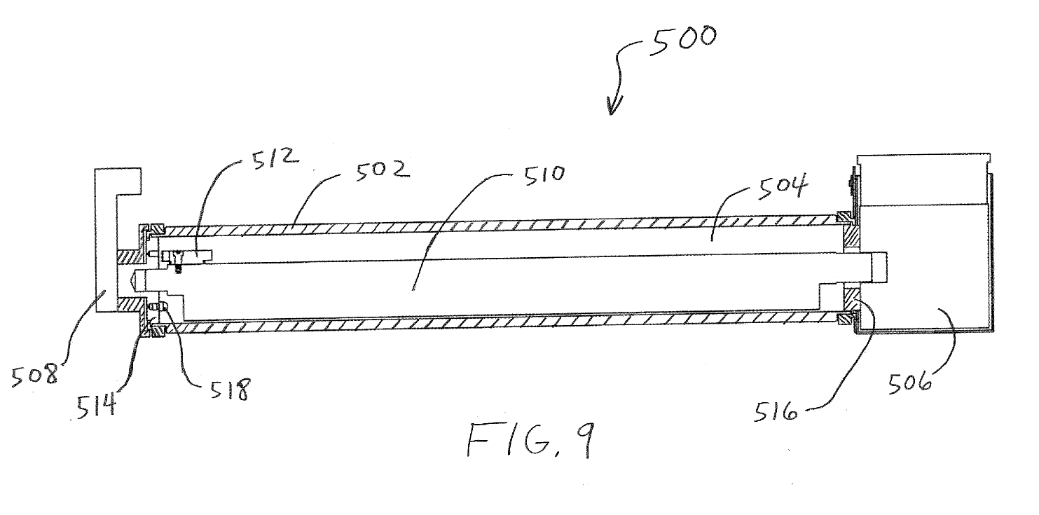

FIG. 8 illustrates a magnetron sputtering apparatus 400 according to one embodiment that includes at least one rotary cathode 402 having the indexing magnet assembly described previously. The rotary cathode 402 includes a target cylinder 404 with a target material layer 405 on an outer surface thereof. The target cylinder 404 has an interior passageway 406, and an end cap 408 is affixed at a distal end of target cylinder 404. The rotary cathode 402 is located within a vacuum chamber 409. A coolant tube 410 is positioned within interior passageway 406 of target cylinder 404.

The indexing magnet assembly includes a stiffening structure 412 located within interior passageway 406. The stiffening structure 412 at least partially surrounds coolant tube 410, and stiffening structure 412 is laterally movable with respect to coolant tube 410. A magnet bar 414 extends substantially parallel to coolant tube 410 and is spaced apart from coolant tube 410 with uniformity adjustment spacers. The magnet bar 414 is connected to stiffening structure 412 and is laterally movable with stiffening structure 412. An indexing wheel 416 is rotatably attached to a distal end of coolant tube 410. A connecting arm 418 is attached to indexing wheel 416 and a tube clamp.

A cathode source assembly 420 includes a cathode end block 422, to which a proximal end of target cylinder 404 is coupled in vacuum chamber 409. The end block 422 is also attached to a vacuum chamber wall 424. A drive housing 426 is located outside of vacuum chamber 409 and is operatively coupled to end block 422 through vacuum chamber wall 424. A motor 428 is mounted on drive housing 426. An attachment mechanism 430 rotatably couples end cap 408 to an interior surface of vacuum chamber wall 424 to support rotary cathode 402 in a horizontal position. Additionally, in other embodiments multiple rotary cathodes can be employed in the magnetron sputtering apparatus.

The enlarged sectional view of rotary cathode 402 in FIG. 8 depicts an eroded target area profile 432 for target material 405 on the outer surface of target cylinder 404. The eroded target area has a substantially uniform erosion profile as the target material between each end of the target cylinder is more fully utilized. In this embodiment, there is a significantly greater amount of target material utilization compared to the embodiment of FIG. 7. Thus, the use of the indexing magnet assembly within the rotary cathode accounts for a substantial increase in target material utilization over the rotary cathode without the indexing magnet assembly.

FIG. 9 illustrates a rotary cathode 500, which includes an indexing magnet assembly according to a further embodiment. The rotary cathode 500 has a rotatable target cylinder 502 with an interior passageway 504. The rotary cathode 500 is removably coupled to a cathode end block 506, which contains a rotary drive mechanism for providing rotational motion to rotary cathode 500. An outboard support structure 508 is coupled to an opposite end of rotary cathode 500 to provide horizontal support.

In the embodiment of FIG. 9, the coolant tube and magnet bar are combined such that the magnet bar is rigidly mounted to the coolant tube and moves with the coolant tube. For example, the magnet bar and coolant tube can be a unitary magnet tube structure 510 that moves in a lateral direction. An indexing wheel 512 rotates around a point off its center, such as to create lateral motion of magnet tube structure 510. The target cylinder 502 is rigidly attached to capping structures, such as a target end cap 514 and a target mounting flange 516. As target cylinder 502 rotates on its axis, there is mechanical interaction between one of the capping structures, rotating with target cylinder 506, and magnet tube structure 510 that does not rotate with target cylinder 502. In one embodiment, this interaction is caused by a drive pin 518 engaging with indexing wheel 512. One or more drive pins may be used, and these drive pins may be mounted on either capping structure. The indexing wheel 512 is partially turned when engaged by the pin, causing indexing wheel 512 to pull or push on magnet tube structure 510 in a lateral direction.

The present invention may be embodied in other specific forms without departing from its essential characteristics. The described embodiments are to be considered in all respects only as illustrative and not restrictive. The scope of the invention is therefore indicated by the appended claims rather than by the foregoing description. All changes that come within the meaning and range of equivalency of the claims are to be embraced within their scope.

What is claimed is:

1. A magnet assembly for a rotary cathode having a rotatable target cylinder, the magnet assembly comprising:
a coolant tube configured to be positioned within the target cylinder; and
a magnet bar configured to be positioned within the target cylinder and extending substantially parallel to the coolant tube;
wherein the magnet bar moves laterally with respect to the target cylinder in a synchronous manner with rotation of the target cylinder.

2. The magnet assembly of claim 1, wherein the magnet bar is slidably mounted to the coolant tube and moves independently of the coolant tube.

3. The magnet assembly of claim 2, further comprising an indexing wheel rotatably attached to the coolant tube, and a connecting arm attached to the indexing wheel.

4. The magnet assembly of claim 3, further comprising a first capping structure mounted at a first end of the target cylinder, and a second capping structure mounted at an opposite second end of the target cylinder.

5. The magnet assembly of claim 4, further comprising at least one drive pin mounted on one of the first or second capping structures.

6. The magnet assembly of claim 5, wherein the indexing wheel is partially turned when engaged by the pin during rotation of the target cylinder, causing the indexing wheel to pull or push on the connecting arm, which moves the magnet bar laterally with respect to the target cylinder.

7. The magnet assembly of claim 1, wherein the magnet bar is rigidly mounted to the coolant tube and moves with the coolant tube.

8. The magnet assembly of claim 7, wherein the magnet bar and coolant tube are combined in a unitary structure that moves in a lateral direction.

9. The magnet assembly of claim 7, further comprising an indexing wheel rotatably attached to the coolant tube.

10. The magnet assembly of claim 9, further comprising a first capping structure mounted at a first end of the target cylinder, and a second capping structure mounted at an opposite second end of the target cylinder.

11. The magnet assembly of claim 10, further comprising at least one drive pin mounted on one of the first or second capping structures.

12. The magnet assembly of claim 11, wherein the indexing wheel is partially turned when engaged by the drive pin during rotation of the target cylinder, causing the indexing wheel to move the coolant tube and magnet bar laterally with respect to the target cylinder.

13. A rotary cathode comprising the magnet assembly according to claim 1.

14. An indexing magnet assembly, comprising:
a tube having a proximal end and a distal end;
a stiffening structure at least partially surrounding the tube and laterally movable with respect to the tube;
a magnet bar extending substantially parallel to the tube and spaced apart from the tube, the magnet bar laterally movable with the stiffening structure;
an indexing wheel rotatably attached to the distal end of the tube; and
a connecting arm attached to the indexing wheel;
wherein as the indexing wheel rotates, the connecting arm moves the stiffening structure and magnet bar in a lateral direction with respect to the tube in a synchronous manner.

15. The indexing magnet assembly of claim 14, further comprising at least one support disc affixed to the tube and protruding outside of an aperture in the stiffening structure.

16. The indexing magnet assembly of claim 15, further comprising at least one tube clamp connected to the stiffening structure and the connecting arm.

17. The indexing magnet assembly of claim 16, wherein the tube clamp comprises:
a support plate attached to the magnet bar; and
at least one uniformity adjustment spacer interposed between the support plate and the tube.

18. A rotary cathode comprising the indexing magnet assembly according to claim 14.

19. A magnetron sputtering apparatus comprising at least one rotary cathode including the indexing magnet assembly according to claim 14.

20. A rotary cathode for a magnetron sputtering apparatus, the rotary cathode comprising:
a rotatable target cylinder having an outer surface and an interior passageway, the target cylinder having a proximal end and a distal end;
an end cap affixed at the distal end of the target cylinder, the end cap having an inner surface facing the interior passageway;
a coolant tube positioned within the interior passageway from the proximal end to the distal end of the target cylinder;
a stiffening structure located within the interior passageway and laterally movable with respect to the coolant tube;
a magnet bar extending substantially parallel to the coolant tube and spaced apart from the coolant tube, the magnet bar connected to the stiffening structure and laterally movable with the stiffening structure;
an indexing wheel rotatably attached to the coolant tube; and
a connecting arm attached off center to the indexing wheel;
wherein as the target cylinder rotates, the indexing wheel is incrementally moved such that the connecting arm pushes or pulls the stiffening structure and magnet bar in a lateral direction with respect to the target cylinder.
